(19) United States
(12) Patent Application Publication
(10) Pub. No.: US 2024/0117495 A1
(43) Pub. Date: Apr. 11, 2024

(54) COLD THERMAL CHEMICAL VAPOR DEPOSITION

(71) Applicant: SILCOTEK CORP., Bellefonte, PA (US)

(72) Inventors: Geoffrey K. WHITE, State College, PA (US); Nicholas P. DESKEVICH, Holidaysburg, PA (US); James B. MATTZELA, Port Matilda, PA (US); Gary A. BARONE, State College, PA (US); David A. SMITH, Bellefonte, PA (US); Pierre A. LECLAIR, Spring Mills, PA (US); Min YUAN, State College, PA (US); Jesse BISCHOF, State College, PA (US)

(21) Appl. No.: 17/768,249

(22) PCT Filed: Oct. 13, 2020
(86) PCT No.: PCT/US2020/055322

§ 371 Date: Apr. 12, 2022

Related U.S. Application Data
(60) Provisional application No. 62/914,607, filed on Oct. 14, 2019.

(51) Int. Cl. C23C 16/52; C23C 16/44; C23C 16/455; C23C 16/46

(52) U.S. Cl. CPC C23C 16/52; C23C 16/4404; C23C 16/45523; C23C 16/46

(57) ABSTRACT

Cold thermal chemical vapor deposition coatings, articles, and processes are disclosed. Specifically, a cold thermal chemical vapor deposition process includes positioning an article, heating a precursor gas to at least a decomposition temperature of the precursor gas to produce a deposition gas, introducing the deposition gas to a coating vessel, and depositing a coating from the deposition gas onto the article within the coating vessel. The article remains at a temperature below the decomposition temperature throughout the introducing and depositing of the deposition gas. The coating on the article has a gradient formed by the depositing of the coating having no flow for a period of time. The coated article includes a thermally-sensitive substrate (the thermally-sensitive substrate capable of being modified by a temperature of 300 degrees Celsius) and a coating the thermally-sensitive substrate.

### FIELD OF THE INVENTION

The present invention is directed to coatings, systems for applying coatings, processes of applying coatings, and coated articles. More particularly, the present invention is thermal chemical vapor deposition.

### BACKGROUND OF THE INVENTION

Flow-through deposition techniques are well known and include plasma enhanced chemical vapor deposition (PECVD), hot wire chemical vapor deposition (HWCVD), atomic layer deposition (ALD), molecular layer deposition (MLD), and other similar techniques. Such techniques can provide uniform composition and/or density of a coating from a bulk/substrate to the surface of the coating. In general, such techniques are popular with those seeking to maintain highly precise compositions and/or density uniformity. They also can be popular in maintaining low temperatures for articles to be coated. Such techniques, however, often suffer from drawbacks of not being cost effective or not being able to coat complex geometries that have non-line-of-sight surfaces and/or high aspect ratios.

Thermal chemical vapor deposition (thermal CVD) techniques are known to be able to coat complex geometries and/or high aspect ratios. Thermal CVD, however, involves heating precursor gases to decomposition temperatures that can degrade materials such as certain grades of aluminum, polymeric/plastic materials, fabrics, or other thermally-sensitive materials.

Techniques for applying depositions to complex geometries and/or high aspect ratios without reaching decomposition temperatures would be desirable in the art.

### BRIEF DESCRIPTION OF THE INVENTION

In an embodiment, a cold thermal chemical vapor deposition process includes positioning an article, heating a precursor gas to at least a decomposition temperature of the precursor gas to produce a deposition gas, introducing the deposition gas to a chamber, and depositing a coating from the deposition gas onto the article within the chamber. The article remains at a temperature below the decomposition temperature throughout the introducing and depositing of the deposition gas. The coating on the article has a gradient formed by the depositing of the coating having no flow for a period of time.

In another embodiment, a cold thermal chemical vapor deposition process includes positioning an article in a coating vessel, heating a precursor gas in a heating chamber (the heating being to at least a decomposition temperature of the precursor gas to produce a deposition gas in the heating chamber), transporting the deposition gas from the heating chamber to the coating vessel, and depositing a coating from the deposition gas onto the article within the coating vessel, while flow of the deposition gas is restricted or halted. The article remains at a temperature below the decomposition temperature throughout the introducing and depositing of the deposition gas.

In another embodiment, a coated article includes a thermally-sensitive substrate (the thermally-sensitive substrate capable of being modified by a temperature of 300 degrees Celsius) and a coating on the thermally-sensitive substrate. The coating has one or both of a compositional gradient and a density gradient.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a schematic perspective view of a thermal chemical vapor deposition process, according to an embodiment of the disclosure.

FIG. 2 is a spectroscopic representation of a coated article, according to an embodiment of the disclosure.

FIG. 3 is an embodiment of a system configured to produce an embodiment of a coated article according to an embodiment of a coating process, according to the disclosure.

Wherever possible, the same reference numbers will be used throughout the drawings to represent the same parts.

### DETAILED DESCRIPTION OF THE INVENTION

Provided are cold thermal chemical vapor deposition coatings, articles, systems, and processes. Embodiments of the present disclosure, for example, in comparison to concepts failing to include one or more of the features disclosed herein, increase consistency/repeatability of treatment, reduce or eliminate effects of residual materials thermally processed, increase inertness (for example, by reduction or elimination of atomic or molecular adsorption and/or by reduction or elimination of metal ion migration), increase resistance to sulfur adsorption, homogenize aesthetics, modify microstructure, modify optical properties, modify porosity, modify corrosion resistance, modify gloss, modify surface features, permit more efficient production of treatments, permit treatment of a wide range of geometries/high aspect ratios (for example, narrow channels/tubes, three-dimensionally complex geometries, tortuous paths, and/or hidden or non-line-of-site geometries, such as, in needles, tubes, probes, fixtures, complex planar and/or non-planar geometry articles, simple non-planar and/or planar geometry articles, and combinations thereof), reduce or eliminate defects/microporosity, permit treatment of a bulk of articles, are capable or being used in or replacing components that are used in industries traditionally believed to be too sensitive for processes that are not flow-through processes (for example, based upon compositional purity, presence of contaminants, thickness uniformity, and/or amount of gas phase nucleation embedded within), allow materials to be used as a substrate that would otherwise produce an electrical arc in a plasma environment, or permit a combination thereof.

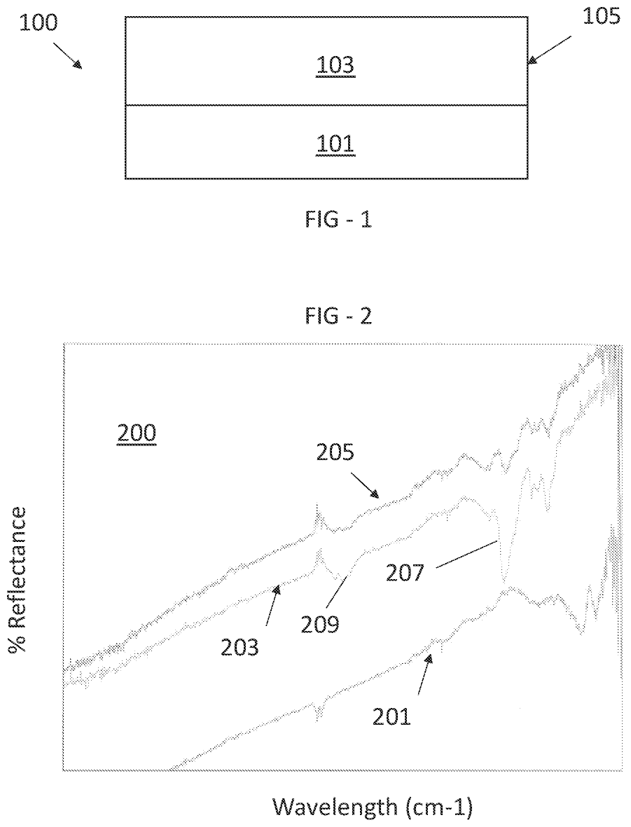

Referring to FIG. 1, in one embodiment, a coated article 100 includes a thermally-sensitive substrate 101. The thermally-sensitive substrate 101 is capable of being modified at a relatively low temperature, for example, less than 300 degrees Celsius, less than 200 degrees Celsius, less than 100 degrees Celsius, less than 50 degrees Celsius, less than 35 degrees Celsius, between 30 degrees Celsius and 300 degrees Celsius, between 100 degrees Celsius and 300 degrees Celsius, between 50 degrees Celsius and 300 degrees Celsius, between 50 degrees Celsius and 200 degrees Celsius, between 100 degrees Celsius and 200 degrees Celsius, or any suitable combination, sub-combination, range, or sub-range therein. Examples of being modified include melting, softening, burning, decomposing, being heat-affected, phase changing, embrittling, crystallizing, vaporizing, having a compositional migration (for example, creating precipitates and/or sensitizing), reacting, impacting mechanical properties (for example, modifying tensile strength), non-reversible heat affects (for example, warping, thermally expanding, distorting), or a combination thereof.

Suitable thermally-sensitive substrates 101 include materials modified at the relatively low temperature. For example, exemplary thermally-sensitive substrates 101 include, but are not limited to, metals, metallic materials (such as, aluminum alloys), polymeric/plastic materials (such as, polyethylene terephthalate), wood products (such as, cellulosic materials), glass, powders, rubbers, carbon fiber, graphite, ceramic, silicon, elastomeric materials, fluoro-polymers, and/or fabrics (such as, cotton or canvas).

The coated article 100 includes a coating 103. The coating 103 is or includes one or more layers directly or indirectly on the thermally-sensitive substrate 101. According to various embodiments, the one or more layers is or include an oxide layer, an intermediate layer, a first layer, a second layer, functionalization layer, a surface layer, a substrate-contacting layer, a passivation layer, any other suitable interface, or a combination thereof.

In one embodiment, the coating 103 has characteristics from being applied through a thermal chemical vapor deposition process, such as, a static thermal chemical vapor deposition process or starved reactor chemical vapor deposition process. The characteristic(s) differentiate in comparison for flow-through techniques, such as PECVD, HWCVD, ALD, and/or MLD. One suitable characteristic is gradient 105, such as, a compositional gradient and/or a density gradient. Yet another suitable characteristic is the complex geometry and/or aspect ratio of a surface having the coating 103. For example, depending upon the configuration, the coating 103 is capable of being applied to regions with aspect ratios greater than 10, greater than 100, greater than 1,000, greater than 5,000, greater than 10,000, or even greater than 100,000 (such as, with tubing having a narrow diameter and long length).

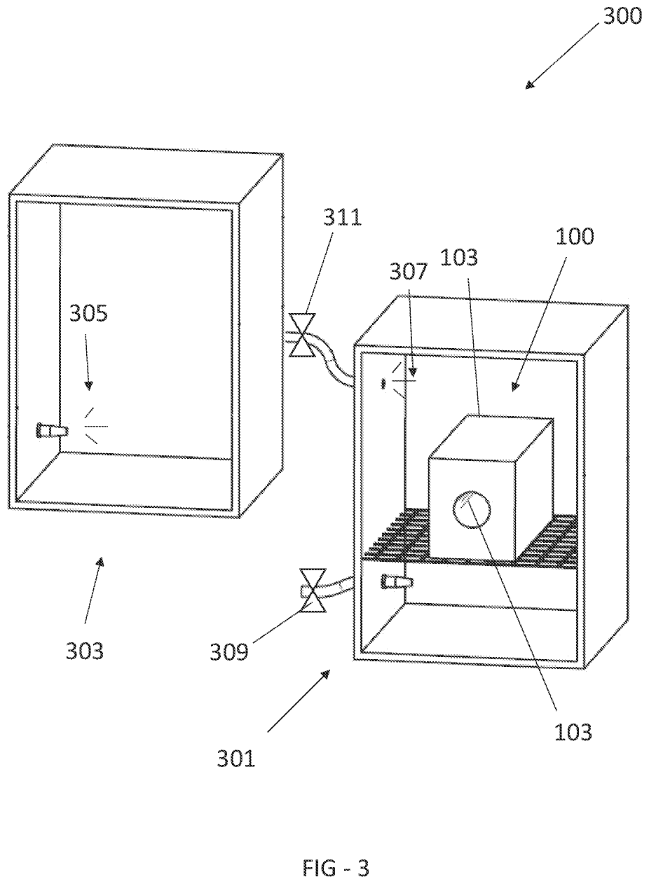

Referring to FIG. 3, in one embodiment, the coated article 100 is produced by a process of positioning an uncoated article (not shown) in a coating vessel 301, heating a precursor gas 305 in a heating chamber 303, the heating being to at least a decomposition temperature of the precursor gas 305 to produce a deposition gas 307 (see the coating vessel 301) in the heating chamber 303, transporting the deposition gas 307 from the heating chamber 303 to the coating vessel 301, and depositing the coating 103 from the deposition gas 307 to onto the uncoated article within the coating vessel 301, while flow of the deposition gas 307 is halted, for example, with an exhaust valve 309 and/or an inlet valve 311 being closed. Additionally or alternatively, in some embodiments, the exhaust valve 309 and/or the inlet valve 311 are partially restricted to retard flow, are pressurized (negatively or positively), are connected to other vessels/chambers, or a combination thereof.

The process is capable of being performed on articles having the thermally-sensitive substrate 101 and/or on articles without such thermal limitations. For example, referring to FIG. 2, a spectroscopic characterization 200 of the coated article 100 according to an embodiment, shows a 316 stainless steel infrared reflectance reference 201 compared a 316 stainless steel dull side infrared reflectance 205 and a 316 stainless steel shiny side infrared reflectance 203 of the coated article 100, coated according to the process. As shown in FIG. 2, the coated article includes a first peak 207 and a second peak 209 illustrating notable compositional differences from the 316 stainless steel infrared reflectance reference 201. The coated article 100 also includes contact angles over 100 degrees, in comparison to corresponding contact angles of less than 90 degrees for 316 stainless steel.

The precursor gas 305 is or includes materials capable of thermal decomposition and deposition. Suitable such materials include, but are not limited to, silane, silane and ethylene, silane and an oxidizer, dimethylsilane, dimethylsilane and an oxidizer, trimethylsilane, trimethylsilane and an oxidizer, dialkylsilyl dihydride, alkylsilyl trihydride, non-pyrophoric species (for example, dialkylsilyl dihydride and/or alkylsilyl trihydride), thermally-reacted material (for example, carbosilane and/or carboxysilane, such as, amorphous carbosilane and/or amorphous carboxysilane), species capable of a recombination of carbosilyl (disilyl or trisilyl fragments), methyltrimethoxysilane, methyltriethoxysilane, dimethydimethoxysilane, dimethyldiethoxysilane, trimethylmethoxysilane, trimethylethoxysilane, ammonia, hydrazine, trisilylamine, Bis(tertiary-butylamino)silane, 1,2-bis(dimethylamino)tetramethyldisilane, dichlorosilane, hexachlorodisilane), organofluorotrialkoxysilane, organofluorosilylhydride, organofluorosilyl, fluorinated alkoxysilane, fluoroalkylsilane, fluorosilane, ttidecafluoro 1,1,2,2-tetrahydrooctylsilane, (tridecafluoro-1,1,2,2-tetrahydrooctyl) triethoxysilane, triethoxy (3,3,4,4,5,5,6,6,7,7,8,8,8-tridecafluoro-1-octyl) silane, (perfluorohexylethyl) triethoxysilane, silane (3,3,4,4,5,5,6,6,7,7,8,9,10,10-heptadecafluorodecyl) trimethoxy-, or a combination thereof.

The heating chamber 303 is any suitable device or system capable of heating or including elements capable of heating the precursor gas 305 to form the deposition gas 307. Suitable embodiments include the heating chamber 303 being one or more tubes, one or more cylinders, one or more spheres, one or more coils, one or more cuboid geometry enclosures, other suitable devices for heating, or a combination thereof. In one embodiment, the heating chamber 303 is or includes features described in U.S. Patent Application Publication No. 2016/0053375 entitled “Chemical Vapor Deposition System Arrangement,” the entirety of which is incorporated by reference.

The the deposition gas 307 is transported from the heating chamber 303 to the coating vessel 301 or a plurality of the coating vessels 301 through any suitable techniques. In one embodiment, the transporting is through a pressure differential, where the vessel 301 has lower pressure compared to the heating chamber 303. In another embodiment, the transporting is through introduction of an inert gas to the heating chamber 303, thereby resulting in the deposition gas 307 being urged into the vessel 301.

The coating vessel 301 includes any suitable configuration permitting the coating 103 to be applied without the coated article 100 ever being at a temperature above the decomposition temperature throughout the introducing and depositing of the deposition gas. For example, in one embodiment with the precursor gas 305 having a decomposition temperature that is greater than 300 degrees Celsius (for example, between 300 degrees Celsius and 600 degrees Celsius), the coating 103 on the coated article 100 is applied within the coating vessel 301 at a temperature of less than 200 degrees Celsius.

The coating vessel 301 has any dimensions or geometry that allow suitable temperatures and pressures, for example, having a minimum width of greater than 5 cm, greater than 10 cm, greater than 20 cm, greater than 30 cm, greater than 100 cm, greater than 300 cm, greater than 1,000 cm, between 10 cm and 100 cm, between 100 cm and 300 cm, between 100 cm and 1,000 cm, between 300 cm and 1,000 cm, any other minimum width capable of uniform or substantially uniform heating, or any suitable combination, sub-combination, range, or sub-range therein. Suitable volumes for the coating vessel 301 include, but are not limited to, at least 1,000 cm³, greater than 3,000 cm³, greater than 5,000 cm³, greater than 10,000 cm³, greater than 20,000 cm³, between 3,000 cm³ and 5,000 cm³, between 5,000 cm³ and 10,000 cm³, between 5,000 cm³ and 20,000 cm³, between 10,000 cm³ and 20,000 cm³, any other volumes capable of uniform or substantially uniform heating, or any suitable combination, sub-combination, range, or sub-range therein.

In one embodiment, the coated article 100 itself defines the coating vessel 301, for example, with only an interior surface of the coated article 100 being coated. For example, in such embodiments, the coated article 100 is capable of being tubing, a cylinder, a sphere, or any other vessel capable of containing the deposition gas 307 during the coating process.

### Examples

In a series of examples, an uncoated article is positioned within the coating vessel 301 fluidly connected to the heating chamber 303. The coating vessel 301 remains at a temperature of between 25 degrees Celsius and 40 degrees Celsius, while the heating chamber 303 heats to temperatures between 300 degrees Celsius and 500 degrees Celsius. The precursor gas 305 is heated within the heating chamber 303, thereby forming the deposition gas 303, prior to it being introduced to the coating vessel 301 and an article positioned within the coating vessel 301 to produce the coated article 100. The water contact angle of the coated article 100 is measured and shown below:

TABLE 1

| | | WATER |
|---|---|---|
| | | CONTACT |
| EXAMPLE | SUBSTRATE | ANGLE |
| Control A (shiny side) | 316 Stainless Steel | 86 |
| Control A (dull side) | 316 Stainless Steel | 94 |
| Example 1 (shiny side) | 316 Stainless Steel | 107 |
| Example 1 (dull side) | 316 Stainless Steel | 111 |
| Control B | Polyethylene Terephthalate | 85.5 |
| Example 2 | Polyethylene Terephthalate | 100 |

Example 1 and Control A correspond with the spectroscopic representation 200 of FIG. 2. The Control A (shiny side) corresponds with the 316 stainless steel infrared reflectance reference 201 in FIG. 2. The Example 1 (dull side) corresponds with the 316 stainless steel dull side infrared reflectance 205 in FIG. 2. The Example 1 (shiny side) corresponds with the 316 stainless steel shiny side infrared reflectance 203 in FIG. 2.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A cold thermal chemical vapor deposition process, comprising:
positioning an article;
heating a precursor gas to at least a decomposition temperature of the precursor gas to produce a deposition gas;
introducing the deposition gas to a coating vessel; and
depositing a coating from the deposition gas onto the article within the coating vessel;
wherein the article remains at a temperature below the decomposition temperature throughout the introducing and depositing of the deposition gas;
wherein the coating on the article has a gradient formed by the depositing of the coating having no flow for a period of time.

2. The cold thermal chemical vapor deposition process of claim 1, wherein the article has a surface that is not capable of being coated by line-of-sight coating techniques.

3. The cold thermal chemical vapor deposition process of claim 1, wherein the article has a surface having an aspect ratio of at least 10.

4. The cold thermal chemical vapor deposition process of claim 1, wherein the article has a metal substrate.

5. The cold thermal chemical vapor deposition process of claim 1, wherein the article has a metallic substrate.

6. The cold thermal chemical vapor deposition process of claim 1, wherein the article has an aluminum substrate.

7. The cold thermal chemical vapor deposition process of claim 1, wherein the article has a plastic substrate.

8. The cold thermal chemical vapor deposition process of claim 1, wherein the article has a cellulosic substrate.

9. The cold thermal chemical vapor disposition process of claim 1, wherein the article is fabric.

10. The cold thermal chemical vapor deposition process of claim 1, wherein the positioning of the article is within the coating vessel.

11. The cold thermal chemical vapor deposition process of claim 1, wherein the positioning of the article includes the article being the coating vessel.

12. The cold thermal chemical vapor deposition process of claim 1, wherein the precursor gas include silane.

13. The cold thermal chemical vapor deposition process of claim 1, wherein the precursor gas include carbon groups and silane groups.

14. The cold thermal chemical vapor deposition process of claim 1, wherein the decomposition temperature is greater than 300 degrees Celsius and the temperature of the article throughout the introducing and depositing of the deposition gas is less than 200 degrees Celsius.

15. The cold thermal chemical vapor deposition process of claim 1, wherein the decomposition temperature is between 300 degrees Celsius and 600 degrees Celsius and the temperature of the article throughout the introducing and depositing of the deposition gas is less than 200 degrees C.

16. The cold thermal chemical vapor deposition process of claim 1, wherein the decomposition temperature is between 300 degrees Celsius and 600 degrees Celsius and the temperature of the article throughout the introducing and depositing of the deposition gas is less than 100 degrees Celsius.

17. The cold thermal chemical vapor deposition process of claim 1, wherein the decomposition temperature is between 300 degrees Celsius and 600 degrees Celsius and the temperature of the article throughout the introducing and depositing of the deposition gas is less than 50 degrees Celsius.

18. A system capable of performing the process of claim 1.

19. A cold thermal chemical vapor deposition process, comprising:
positioning an article in a coating vessel;
heating a precursor gas in a heating chamber, the heating being to at least a decomposition temperature of the precursor gas to produce a deposition gas in the heating chamber;
transporting the deposition gas from the heating amber to the coating vessel; and
depositing a coating from the deposition gas onto the article within the coating vessel, while flow of the deposition gas is restricted or halted;
wherein the article remains at a temperature below the decomposition temperature throughout the introducing and depositing of the deposition gas.

20. A coated article, comprising:
a thermally-sensitive substrate, the thermally-sensitive substrate capable of being modified by a temperature of 300 degrees Celsius; and
a coating on the thermally-sensitive substrate;
wherein the coating has one or both of a compositional gradient and a density gradient.
